(19) United States
(12) Patent Application Publication
(10) Pub. No.: US 2026/0068030 A1
(43) Pub. Date: Mar. 5, 2026

(54) THERMAL INTERFACE MATERIAL INSTALLATION DEVICE

(71) Applicant: LENOVO ENTERPRISE SOLUTIONS (SINGAPORE) PTE LTD., SINGAPORE (SG)

(72) Inventors: ARVIND MODEKURTI, MORRISVILLE, NC (US); JEFFREY S. HOLLAND, MORRISVILLE, NC (US); BEJOY J. KOCHUPARAMBIL, APEX, NC (US)

(21) Appl. No.: 18/817,745

(22) Filed: Aug. 28, 2024

(51) Int. Cl. H05K 1/02

(52) U.S. Cl. CPC H05K 1/0209; H05K 2201/10598

(57) ABSTRACT

Methods, systems, and apparatus for installing a TIM installation device include positioning, on a computer component, a carrier comprising multiple cutouts, where multiple TIMs are positioned on the carrier over the multiple cutouts, positioning a heat sink on the carrier, where the carrier is positioned between the computer component and the heat sink, and coupling the heat sink to the computer component, including compressing the multiple TIMs into the multiple cutouts to be in thermal contact with both the heat sink and the computer component.

### BACKGROUND

The present disclosure relates to methods, apparatus, and systems for installing a thermal interface material installation device.

### SUMMARY

Methods, systems, and apparatus for installing a thermal interface material (TIM) installation device according to various embodiments are disclosed in this specification. In accordance with one aspect of the present disclosure, a method of installing a TIM installation device includes positioning, on a computer component, a carrier comprising multiple cutouts, where multiple TIMs are positioned on the carrier over the multiple cutouts, positioning a heat sink on the carrier, where the carrier is positioned between the computer component and the heat sink, and coupling the heat sink to the computer component, including compressing the multiple TIMs into the multiple cutouts to be in thermal contact with both the heat sink and the computer component.

In accordance with another aspect of the present disclosure, leak prevention and detection in liquid-cooled packages may include a system including: a computer component, a carrier having multiple cutouts and multiple TIMs positioned on a top surface of the carrier over the multiple cutouts, where a bottom surface of the carrier is positioned on the computer component, and a heat sink coupled to the computer component, where the multiple TIMs are in thermal contact with the heat sink and with the computer component through the multiple cutouts.

The foregoing and other objects, features and advantages of the disclosure will be apparent from the following more particular descriptions of exemplary embodiments of the disclosure as illustrated in the accompanying drawings wherein like reference numbers generally represent like parts of exemplary embodiments of the disclosure.

### BRIEF DESCRIPTION OF THE DRAWINGS

FIG. 1 shows an example block diagram of a conventional system with TIMs installed in accordance with embodiments of the present disclosure.

FIG. 2 shows an example line drawing of a TIM installation device in accordance with embodiments of the present disclosure.

FIG. 3 shows an example line drawing of a TIM installation device including multiple TIMs in accordance with embodiments of the present disclosure.

FIG. 4 shows an example block diagram of a TIM installation device being installed in a system in accordance with embodiments of the present disclosure.

FIG. 5 shows an example block diagram of a TIM installation device fully installed in a system in accordance with embodiments of the present disclosure.

FIG. 6 is a flowchart of an example method of installing a TIM installation device according to some embodiments of the present disclosure.

### DETAILED DESCRIPTION

The number of components within a server requiring thermal management (local heat sinks, specified airflow, and/or high performance TIMs) is increasing due to increases in component power consumption and/or due to subcomponents increasingly utilizing heat sinks and associated TIMs for cooling. TIMs can include greases, thermal pads, or thermal putty. When servicing these subcomponents, the TIMs can be difficult and time consuming to install due to their small size and relative lack of structure. Further, the handling of the TIMs requires utmost care to avoid damage and contamination. In accordance with the inventive concepts disclosed herein, a TIM installation device and methods of using thereof are provided that allow for the installation of multiple TIMs simultaneously without having to manipulate the TIMs with risk of damage or contamination.

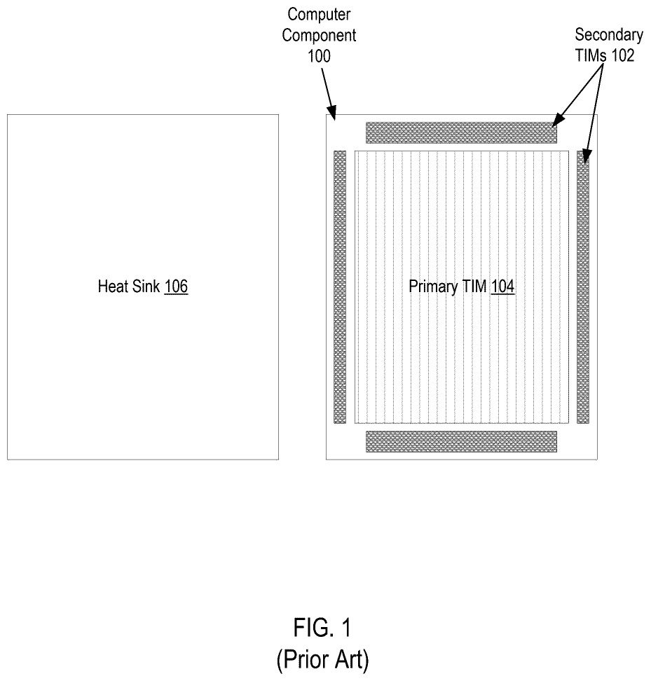

Exemplary methods, systems, and apparatus for installing a TIM installation device in accordance with the present disclosure are described with reference to the accompanying drawings. FIG. 1 sets forth an example block diagram of a conventional system with TIMs installed. FIG. 1 shows a heat sink 106 removed from (such as during service), or not yet installed onto, a computer component 100. FIG. 1 also shows multiple TIMs that are positioned between the computer component 100 and the heat sink when the heat sink is installed on the computer component. Such TIMs include a primary TIM 104, which may include a thermal grease or any other type of TIM, and multiple secondary TIMs 102, which may include a thermal putty or any other type of TIM.

The example computer component 100 of FIG. 1 may be any computer component that may benefit from the cooling properties of being coupled to a heat sink, such as a processor, graphics processing unit (GPU), other accelerator, circuit board, and the like. Conventionally, during initial installation or servicing of the computer, the primary TIM 104 (such as a thermal grease) is not replaced or handled, but the multiple secondary TIMs (which may include thermal putty or a thermal pad) may be replaced and individually positioned at the appropriate locations on the computer component. Handling such secondary TIMs, however, may potentially cause damage or contamination to the secondary TIMs (which, in some cases, may be formed of a relatively fragile material), and the precision needed to place the TIMs correctly may be difficult to achieve and/or time consuming for service personnel.

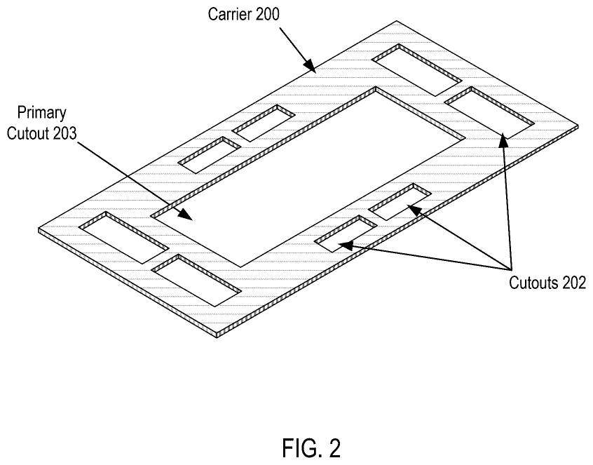

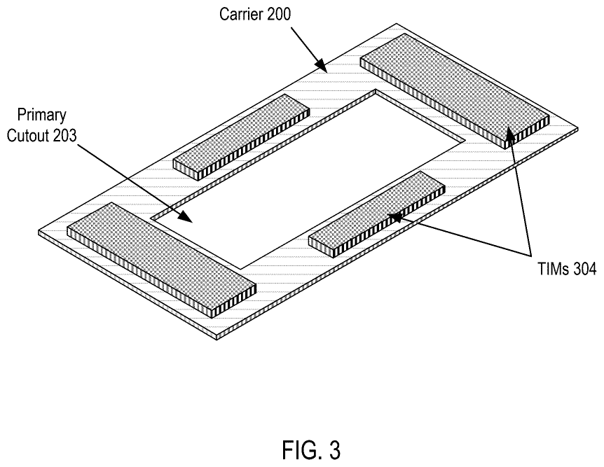

For further explanation, FIG. 2 sets forth an example line drawing of a TIM installation device in accordance with embodiments of the present disclosure. The example TIM installation device of FIG. 2 includes a carrier 200 having multiple holes or openings cut out from the carrier (referred to as ‘cutouts’). In the example of FIG. 2, the carrier 200 includes multiple cutouts 202 positioned around a primary cutout 203. The carrier 200 of FIG. 2 is configured to hold multiple TIMs (such as the secondary TIMs of FIG. 1) positioned over each of the multiple cutouts 202 (see FIG. 3 for more detail). The carrier 200 is configured to be installed with the attached secondary TIMs, whether initially or during service of the computer component, between the computer component and the heat sink. In installing the heat sink to the computer component, with the carrier and the included TIMs positioned on it, the included TIMs can pass through the cutouts so that they become in thermal contact with both the computer component and the heat sink. The primary cutout 203 allows for the primary TIM to pass through the primary cutout during installation. By installing secondary TIMs using the carrier of FIG. 2, the carrier 200 allows for multiple secondary TIMs to be installed simultaneously, thereby decreasing the installation time of the multiple TIMs. Further, the carrier 200 allows for the installation of the secondary TIMs without handling the TIMs directly (such as when the TIMs are already preinstalled on the carrier 200), thereby reducing the chance of damage or contamination to the TIMs.

The example carrier 200 of FIG. 2 may be composed of a stamped material or any metal material, such as copper, stainless steel, galvanized steel, and the like. The height or thinness of the carrier 200 of FIG. 2 may allow the carrier to remain installed between the computer component (such as the computer component 100 of FIG. 1) and the heat sink (such as the heat sink 106 of FIG. 1) without interfering with the effectiveness of the TIMs (including the primary TIM 104, such as a thermal grease). In some embodiments, the bond-line thickness for a primary TIM is less than 0.3 mm thick, whereas the bond-line thickness of a secondary TIM (such as a thermal putty) is greater than 1 mm thick. In some embodiments, the thickness of the carrier 200 is less than 1 mm (such as 0.3 mm), or less than the bond-line thickness of the secondary TIMs, allowing the secondary TIMs to pass through the cutouts of the carrier to thermally contact both a surface of the computer component and a surface of the heat sink.

The example cutouts of the carrier are positioned to align with the specific computer component for which the carrier is designed. That is, a carrier may be configured to align with a specific computer component, where the primary cutout 203 and the multiple cutouts 202 are positioned in the carrier based on the specific computer component or type of computer component. During the initial installation of the carrier, the primary cutout 203 is configured to allow for the application of the primary TIM onto a surface of the computer component. During installation, the primary cutout 203 is configured to prevent the thermal grease (or other primary TIM) from contacting the carrier 200. For example, the primary cutout may be larger in area than the area of the primary TIM on the computer component, thereby allowing for the carrier 200 to be replaced (such as during service of the computer component or heat sink) without contacting or otherwise affecting the primary TIM.

For further explanation, FIG. 3 sets forth an example line drawing of a TIM installation device including multiple TIMs in accordance with embodiments of the present disclosure. The example TIM installation device of FIG. 2 includes the carrier 200 of FIG. 2, but with multiple TIMs 304 positioned on the carrier 200. The multiple TIMs 304 may be similar to the secondary TIMs of FIG. 1 (such as a thermal putty or thermal pad). The TIMs 304 of FIG. 3 are positioned on the carrier 200 over the multiple cutouts 202 of the carrier. In the example of FIG. 3, the multiple TIMs 304 are larger (whether in length, in width, or both) than the cutouts 202 of FIG. 2, allowing the TIMs 304 to sit on the carrier without falling through the cutouts 202. In one embodiment, the cutouts 202 of FIG. 2 may be the same size and shape as the TIMs 304 of FIG. 3, but with tabs protruding from the sides of the cutouts to prevent the TIMs from falling through the cutouts.

In the example of FIG. 3, each of the TIMs 304 covers multiple cutouts (two) of the carrier as an example. However, a carrier configured for use in a TIM installation device in accordance with embodiments of the present disclosure may be constructed in a variety of different configurations. In some embodiments, for example, the carrier may include the same number of cutouts (excluding the primary cutout) as the number of TIMs 304 positioned on the carrier. In the example of FIG. 3, the TIMs (and corresponding cutouts 202) are positioned uniformly or symmetrically around the carrier 200. In another embodiment, any number or position of TIMs 304 (and corresponding cutouts 202) may be positioned on the carrier according to the specific requirements of the computer component on which the carrier is being installed. In the example of FIG. 3, the multiple TIMs 304 all have a uniform (or nearly uniform) thickness. In another embodiment, one or more of the TIMs 304 may have different thicknesses. The term ‘thickness’ as it used here to describe a TIM refers to a height of the TIM as measured orthogonally from a surface of the carrier.

In an embodiment, the carrier 200 may be re-used with new secondary TIMs (such as TIMs 304) during service. In such an embodiment, the TIMs 304 are positioned over the corresponding cutouts of the carrier. In another embodiment, the new TIMs 304 may come pre-installed on a new carrier 200 to be installed during service. When the carrier is correctly aligned and installed on a computer component, the cutouts of the example carrier allow for precise positioning of the contact between the TIMs and the computer component. Further, because the cutouts 202 are smaller than the TIM's positioned on the carrier, less precision is required when placing the TIMs on the carrier when compared to conventional methods of placing the TIMs directly on the computer component. For example, a TIM positioned slightly off center over a cutout will still be compressed into the cutout and contact the computer component at the desired precise position. In contrast, such off center positioning of a TIM directly on the computer component could result in performance issues or errors.

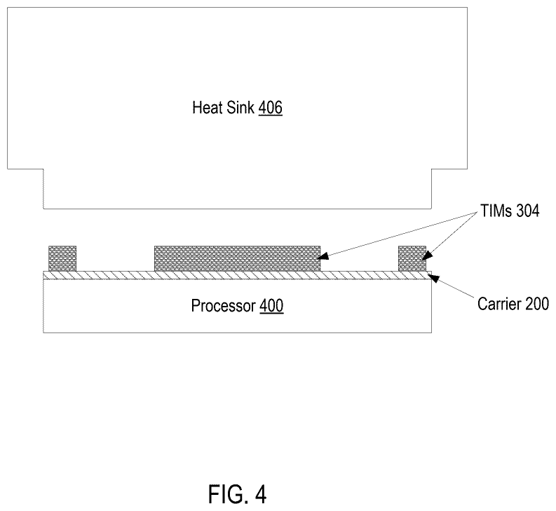

For further explanation, FIG. 4 sets forth an example block diagram of a TIM installation device being installed in a system in accordance with embodiments of the present disclosure.

FIG. 4 shows a carrier 200 with included TIMs 304 positioned on a surface of a processor 400 (an example of a computing component), with a heat sink 406 awaiting installation onto the processor. In the example of FIG. 4, the carrier and included secondary TIMs (such as TIMs 304) are positioned on the computer component (such as processor 400), with the heat sink 406 being positioned over the carrier 200 and TIMs 304 for installation. Prior to the heat sink 406 being installed and torqued down (via screws or bolts) onto the computer component, the TIMs 304 positioned over the cutouts 202 of the carrier are not in full thermal contact with the processor 400. In fact, in some embodiments, the TIMs 304 have no thermal contact with the processor prior to installation of the heat sink 406. Instead, prior to fully coupling the heat sink to the processor, the carrier is in contact with the processor and the TIMs 304 are separated from the processor by a gap equal to the thickness of the carrier 200.

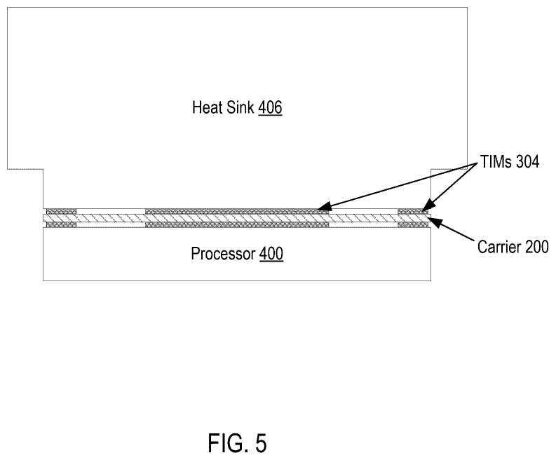

FIG. 5 sets forth an example block diagram of a TIM installation device fully installed in a system in accordance with embodiments of the present disclosure. FIG. 5 shows the heat sink 406 fully installed onto the processor 400, with the secondary TIMs 304 in thermal contact with both the heat sink and the processor. In installing the heat sink to the processor 400, the TIMs 304 are compressed into the cutouts (such as cutouts 202 of FIG. 2) of the carrier 200 to be in thermal contact with both the heat sink and the processor. In the example of FIG. 5, the carrier 200 is shown as being lifted up off of the surface of the processor, where the compressed TIMs 304 are pushed under the carrier (such as at the edges of the cutouts). In another embodiment, the carrier 200 may remain in contact with the computer component as the TIMs are compressed into the cutouts of the carrier. As shown in FIG. 5, the carrier 200 remaining installed does not interfere with the performance of the TIMs 304. Not shown in FIG. 5, the carrier 200 also does not interfere with the performance of the primary TIM (not shown in FIG. 5) between the heat sink and computer component.

In the example of FIG. 4 and FIG. 5, the carrier is shown as being first positioned on the computer component, with the heat sink being installed on top of the carrier. However, in other embodiments, the carrier may be first positioned on a heat sink and then the computer component installed on top of the carrier. In another example, the carrier may be installed upside down (relative to the example provided in FIG. 4) on either the heat sink or computer component, provided that the carrier is correctly aligned according to the computer component and the TIMs 304.

In the example of FIG. 5, the carrier is depicted as being in direct contact with the heat sink. In another embodiment, the carrier may be in contact with a cold plate that is in turn in contact with a heat sink or other cooling device. In some embodiments, the carrier may be installed between the computer component and any other type of cooling device. In the example of FIG. 5, the carrier is shown as being installed directly on a computer component (such as a processor). In another embodiment, the carrier may be positioned on another surface thermally coupled to the computer component for heat transfer without directly contacting the computer component.

The example of FIG. 5 shows a single carrier being installed on a single computer component with a single heat sink. In another embodiment, the carrier may be configured to be installed over multiple computer components at once. In such an embodiment, a single heat sink may be installed on the multiple computer components over the carrier, or multiple heat sinks corresponding to the multiple computer components may be installed over the one carrier. In such an embodiment, the carrier may include multiple primary cutouts corresponding with the computer components. In another embodiment, multiple carriers may be installed on a single computer component. For example, a complex or large computer component may require multiple different carriers to be installed at once, with each carrier having the same or different numbers of primary cutouts and secondary cutouts (for secondary TIMs). In such an embodiment, one or more of the multiple carrier may include only cutouts for secondary TIMs without a primary cutout.

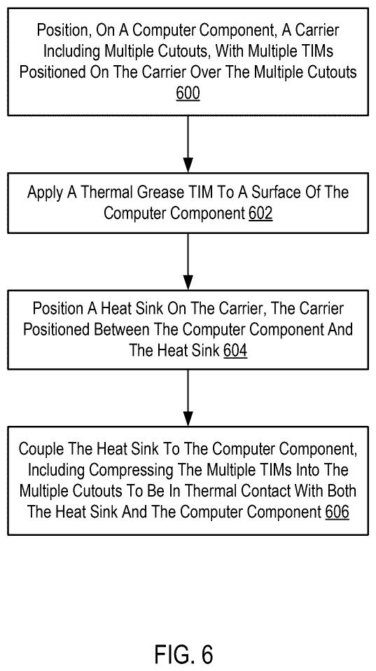

For further explanation, FIG. 6 sets forth a flowchart of an example method of installing a TIM installation device according to some embodiments of the present disclosure. The method of FIG. 6 includes positioning 600, on a computer component, a carrier including multiple cutouts, with multiple TIMs positioned on the carrier over the multiple cutouts. Positioning 600 a carrier on a computer component may be carried out by seating the carrier on a surface of the computer component, including aligning the carrier with the computer component. In some embodiments, the carrier may include tabs, notches, alignment lines, or other mechanisms for correctly aligning and seating the carrier onto the computer component.

The method of FIG. 6 also includes applying 602 a thermal grease TIM to a surface of the computer component. Applying 602 a thermal grease TIM to a surface of the computer component may be carried out by a screen printing technique, allowing for uniform thickness of the thermal grease onto the computer component's surface. In another embodiment, the thermal grease TIM may be applied to the surface of the heat sink which will contact the computer component. In one embodiment, the application 602 of the thermal grease may occur prior to positioning the carrier on the computer component.

The method of FIG. 6 also includes positioning 604 a heat sink on the carrier, the carrier positioned between the computer component and the heat sink. Positioning 604 a heat sink on the carrier may be carried out by placing the heat sink down onto the carrier (such as into contact with the TIMs included on the carrier) while in alignment with the computer component and carrier. For example, the surface of the heat sink contacting the carrier or the carrier included TIMs is positioned directly over the computer component and the carrier.

The method of FIG. 6 also includes coupling 606 the heat sink to the computer component, including compressing the multiple TIMs into the multiple cutouts to be in thermal contact with both the heat sink and the computer component. Coupling 606 the heat sink to the computer component may be carried out via one or more screws, bolts, or other coupling mechanism configured to securely couple the heat sink to the computer component. In coupling the heat sink to the computer component, the TIMs included on the carrier are compressed and pushed into the cutouts of the carrier towards the surface of the computer component until the TIMs are fully in thermal contact with the computer component within the full area of the cutouts.

In view of the explanations set forth above, readers will recognize that the benefits of installing a TIM installation device according to embodiments of the present disclosure include:
Decreasing installation time and difficulty in installing TIMs onto a computer component, including during either initial installation of such TIMs or during service of the computer component or associated cooling component.
Decreasing the chance of damage or contamination to TIMs during installation of the TIMs onto the computer component.

The flowchart and block diagrams in the Figures illustrate the architecture, functionality, and operation of possible implementations of systems, methods, and apparatus according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

It will be understood from the foregoing description that modifications and changes may be made in various embodiments of the present disclosure without departing from its true spirit. The descriptions in this specification are for purposes of illustration only and are not to be construed in a limiting sense. The scope of the present disclosure is limited only by the language of the following claims.

What is claimed is:

1. A method comprising:
positioning, on a computer component, a carrier comprising multiple cutouts, wherein multiple thermal interface materials (TIMs) are respectively positioned on the carrier over the multiple cutouts;
positioning a heat sink on the carrier, wherein the carrier is positioned between the computer component and the heat sink; and
coupling the heat sink to the computer component, including compressing the multiple TIMs into the multiple cutouts to be in thermal contact with both the heat sink and the computer component, wherein the carrier is between the coupled heat sink and computer component.

2. The method of claim 1, wherein the multiple TIMs comprise thermal putty.

3. The method of claim 1, wherein the carrier further comprises a primary cutout, and wherein the method further comprising applying a thermal grease TIM to a surface of the computer component, wherein the primary cutout of the carrier is configured to prevent the carrier from contacting the thermal grease TIM when positioned on the computer component.

4. The method of claim 3, wherein the primary cutout is positioned in a center of the carrier.

5. The method of claim 3, wherein the multiple cutouts are positioned around the primary cutout of the carrier.

6. The method of claim 1, wherein, upon positioning the carrier on the computer component, the multiple TIMs do not contact the computer component until the multiple TIMs are compressed into the multiple cutouts of the carrier.

7. The method of claim 1, wherein the carrier is configured to be installed on multiple computer components simultaneously.

8. The method of claim 1, wherein multiple carriers are configured to be installed on a single computer component.

9. A system comprising:
a computer component;
a carrier comprising multiple cutouts and multiple thermal interface materials (TIMs) positioned on a top surface of the carrier over the multiple cutouts, wherein a bottom surface of the carrier is positioned on the computer component; and
a heat sink coupled to the computer component, wherein the multiple TIMs are in thermal contact with the heat sink and with the computer component through the multiple cutouts, and wherein the carrier is between the computer component and the heat sink.

10. The system of claim 9, wherein the multiple TIMs comprise thermal putty.

11. The system of claim 9, wherein the carrier further comprises a primary cutout, and wherein the system further comprises a thermal grease TIM applied to a surface of the computer component, wherein the primary cutout of the carrier is configured to prevent the carrier from contacting the thermal grease TIM when positioned on the computer component.

12. The system of claim 11, wherein the primary cutout is positioned in a center of the carrier.

13. The system of claim 11, wherein the multiple cutouts are positioned around the primary cutout of the carrier.

14. The system of claim 9, wherein the multiple TIMs are compressed into the multiple cutouts of the carrier by the heat sink coupled to the computer component.

15. The system of claim 9, wherein the carrier is configured to be installed on multiple computer components simultaneously.

16. The system of claim 9, wherein multiple carriers are configured to be installed on a single computer component.

17. An apparatus comprising:
a carrier comprising multiple cutouts, wherein a bottom surface of the carrier is configured to contact a computer component; and
multiple thermal interface materials (TIMs) positioned on a top surface of the carrier over the multiple cutouts;
wherein the carrier and the multiple TIMs are configured to be positioned between the computer component and a heat sink during and after installation of the heat sink onto the computer component, and wherein the multiple TIMs are configured to be compressed by the heat sink into the multiple cutouts and into thermal contact with both the heat sink and the computer component.

18. The apparatus of claim 17, wherein the multiple TIMs comprise thermal putty.

19. The apparatus of claim 17, wherein the carrier further comprises a primary cutout, wherein the primary cutout of the carrier is configured to prevent the carrier from contacting a thermal grease TIM positioned on the computer component.

20. The apparatus of claim 19, wherein the multiple cutouts are positioned around the primary cutout of the carrier.
